(19) United States
(12) Patent Application Publication
(10) Pub. No.: US 2026/0105214 A1
(43) Pub. Date: Apr. 16, 2026

(54) METHOD AND SYSTEM FOR TRAINING A CAR PARTS DETECTOR ON SYNTHETIC DATASET

(71) Applicant: Toyota Research Institute, Inc., Los Altos, CA (US)

(72) Inventors: Kiyomasa Akaike, San Jose, CA (US); Mark E. Tjersland, Mountain View, CA (US)

(73) Assignees: Toyota Research Institute, Inc., Los Altos, CA (US); Toyota Jidosha Kabushiki Kaisha, Toyota-shi (JP)

(21) Appl. No.: 18/916,014

(22) Filed: Oct. 15, 2024

(51) Int. Cl. G06F 30/27; G06F 30/15

(52) U.S. Cl. CPC G06F 30/27; G06F 30/15

(57) ABSTRACT

A method may include selecting one or more virtual car parts, selecting initial positions and initial orientations for the selected one or more virtual car parts in a virtual container, determining resting positions and resting orientations for the selected one or more virtual car parts in the virtual container based on the initial positions, the initial orientations, and a physics simulation, generating an image of the selected one or more virtual car parts in the virtual container at the resting positions and the resting orientations, and generating training data including the generated image as one training example.

### TECHNICAL FIELD

The present specification relates to training a car parts detector, and more particularly to a method and system for training a car parts detector on a synthetic dataset.

### BACKGROUND

A robot may be used to pick car parts from a container. In particular, the robot may capture an image of an open container and identify car parts within the container based on the image. The robot may then pick one or more of the identified car parts using a robot arm or other physical device.

However, current technology cannot localize car parts in images accurately. Identifying specific car parts in images typically requires extensive training of a model, and retraining of the model whenever car parts change (e.g., due to production updates). Moreover, obtaining real data for training a car parts detector presents significant challenges due to the presence of confidential information, such as proprietary manufacturing methods and intricate car part designs. Additionally, it may not be practical to modify lighting conditions or introduce unconventional objects in factories to gather high-quality datasets. Such issues may incur substantial costs, which may hinder factory automation. As such, there is a need for an improved car parts detector.

### SUMMARY

In one embodiment, a method may include selecting one or more virtual car parts, selecting initial positions and initial orientations for the selected one or more virtual car parts in a virtual container, determining resting positions and resting orientations for the selected one or more virtual car parts in the virtual container based on the initial positions, the initial orientations, and a physics simulation, generating an image of the selected one or more virtual car parts in the virtual container at the resting positions and the resting orientations, and generating training data including the generated image as one training example.

In another embodiment, a computing device may include one or more processors configured to select one or more virtual car parts, select initial positions and initial orientations for the selected one or more virtual car parts in a virtual container, determine resting positions and resting orientations for the selected one or more virtual car parts in the virtual container based on the initial positions, the initial orientations, and a physics simulation, generate an image of the selected one or more virtual car parts in the virtual container at the resting positions and the resting orientations, and generate training data including the generated image as one training example.

In another embodiment, a non-transitory computer readable storage medium may include a memory storing a program. When executed by a processor, the processor may select one or more virtual car parts, select initial positions and initial orientations for the selected one or more virtual car parts in a virtual container, determine resting positions and resting orientations for the selected one or more virtual car parts in the virtual container based on the initial positions, the initial orientations, and a physics simulation, generate an image of the selected one or more virtual car parts in the virtual container at the resting positions and the resting orientations, and generate training data including the generated image as one training example.

### BRIEF DESCRIPTION OF THE DRAWINGS

The embodiments set forth in the drawings are illustrative and exemplary in nature and not intended to limit the disclosure. The following detailed description of the illustrative embodiments can be understood when read in conjunction with the following drawings, where like structure is indicated with like reference numerals and in which:

FIG. 1 schematically depicts an example computing device or training a car parts detector on synthetic data, according to one or more embodiments shown and described herein;

FIG. 2 schematically depicts a plurality of memory modules of the computing device of FIG. 1, according to one or more embodiments shown and described herein;

FIG. 3A depicts an example image of virtual car parts in a virtual container, according to one or more embodiments shown and described herein;

FIG. 3B depicts another example image of virtual car parts in a virtual container, according to one or more embodiments shown and described herein;

FIG. 4A depicts another example image of virtual car parts in a virtual container, according to one or more embodiments shown and described herein;

FIG. 4B depicts an example image of virtual car parts with bounding boxes, according to one or more embodiments shown and described herein; and

FIG. 5 depicts a flowchart of an example method for operating the computing device of FIG. 1, according to one or more embodiments shown and described herein.

### DETAILED DESCRIPTION

The embodiments disclosed herein describe methods and systems for training a car parts detector based on synthetic data. In particular, virtual car parts may be randomly selected from a database to be used as training data for a machine learning model. The database may include images of real car parts and/or computer generated images of car parts. The selected car parts may be placed in a virtual container at random positions with random orientations. A physics engine may then be used to allow the virtual car parts to settle at natural resting positions and orientations. An image of the virtual car parts at the resting positions and in the virtual container may then be captured. A random background may be applied to the image. The captured image with the background may be used as one training example.

A large number of training examples may be generated in a similar manner with different virtual car parts, different virtual containers, different positions and orientations of the virtual car parts, and different backgrounds. All of the training examples may be used as training data to train a machine learning model to receive an image including one or more car parts and identify the car parts in the image. A robot may then use the trained machine learning model to identify real car parts in an actual container and pick the identified car parts using a robotic arm or other mechanism.

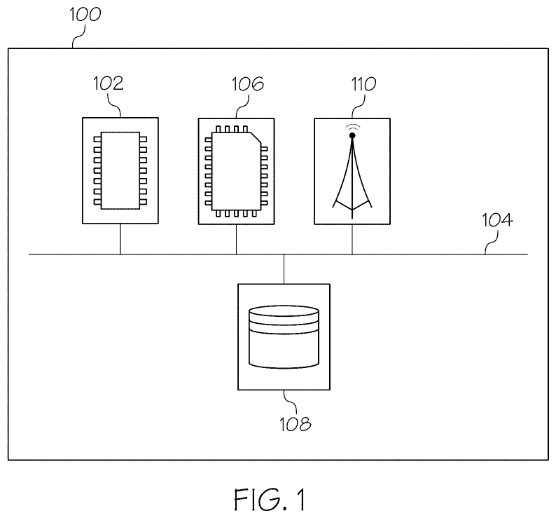

Turning now to the figures, FIG. 1 schematically depicts an example configuration of a computing device 100, according to the embodiments disclosed herein. The computing device 100 may comprise a variety of different types of devices (e.g., a local computing system, a cloud computing system, and the like). The computing device 100 may perform the operations of the embodiments disclosed herein. In the illustrated example, the computing device 100 includes one or more processors 102, a communication path 104, one or more memory modules 106, a data storage component 108, and network interface hardware 110, the details of which will be set forth in the following paragraphs.

Each of the one or more processors 102 may be any device capable of executing machine readable and executable instructions. Accordingly, each of the one or more processors 102 may be a controller, an integrated circuit, a microchip, a computer, or any other physical or cloud-based computing device. The one or more processors 102 are coupled to a communication path 104 that provides signal interconnectivity between various modules of the computing device 100. Accordingly, the communication path 104 may communicatively couple any number of processors 102 with one another, and allow the modules coupled to the communication path 104 to operate in a distributed computing environment. Specifically, each of the modules may operate as a node that may send and/or receive data. As used herein, the term “communicatively coupled” means that coupled components are capable of exchanging data signals with one another such as, for example, electrical signals via conductive medium, electromagnetic signals via air, optical signals via optical waveguides, and the like.

Accordingly, the communication path 104 may be formed from any medium that is capable of transmitting a signal such as, for example, conductive wires, conductive traces, optical waveguides, or the like. In some embodiments, the communication path 104 may facilitate the transmission of wireless signals, such as WiFi, Bluetooth®, Near Field Communication (NFC) and the like. Moreover, the communication path 104 may be formed from a combination of mediums capable of transmitting signals. In one embodiment, the communication path 104 comprises a combination of conductive traces, conductive wires, connectors, and buses that cooperate to permit the transmission of electrical data signals to components such as processors, memories, sensors, input devices, output devices, and communication devices. Additionally, it is noted that the term “signal” means a waveform (e.g., electrical, optical, magnetic, mechanical or electromagnetic), such as DC, AC, sinusoidal-wave, triangular-wave, square-wave, vibration, and the like, capable of traveling through a medium.

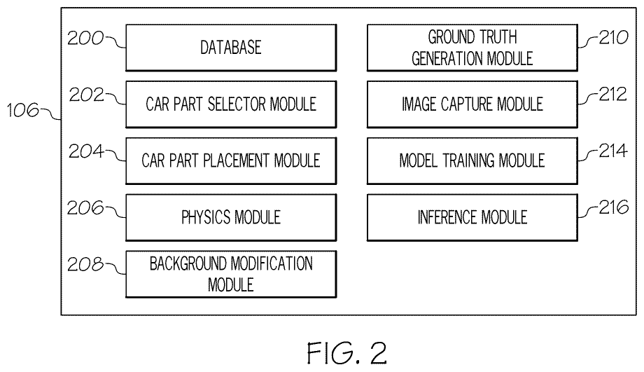

The computing device 100 includes one or more memory modules 106 coupled to the communication path 104. The one or more memory modules 106 may comprise RAM, ROM, flash memories, hard drives, or any device capable of storing machine readable and executable instructions such that the machine readable and executable instructions can be accessed by the one or more processors 102. The machine readable and executable instructions may comprise logic or algorithm(s) written in any programming language of any generation (e.g., 1GL, 2GL, 3GL, 4GL, or 5GL) such as, for example, machine language that may be directly executed by the processor, or assembly language, object-oriented programming (OOP), scripting languages, microcode, etc., that may be compiled or assembled into machine readable and executable instructions and stored on the one or more memory modules 106. Alternatively, the machine readable and executable instructions may be written in a hardware description language (HDL), such as logic implemented via either a field-programmable gate array (FPGA) configuration or an application-specific integrated circuit (ASIC), or their equivalents. Accordingly, the methods described herein may be implemented in any conventional computer programming language, as pre-programmed hardware elements, or as a combination of hardware and software components. The memory modules 106 are discussed in more detail below in connection with FIG. 2.

Referring still to FIG. 1, the example computing device 100 includes a data storage component 108. The data storage component 108 may store data used by the computing device 100. The data storage component 108 may also store other data used by the various components of the computing device 100.

Still referring to FIG. 1, the computing device 100 comprises network interface hardware 110 for communicatively coupling the computing device 100 to the external computing devices. As such, the network interface hardware 110 may send data to and/or receive data from various external computing devices. The network interface hardware 110 may comprise a wired and/or wireless connection to one or more external computing devices. In other examples, the network interface hardware 110 may be send data to and/or receive data from other computing devices.

The network interface hardware 110 can be communicatively coupled to the communication path 104 and can be any device capable of transmitting and/or receiving data via a network. Accordingly, the network interface hardware 110 can include a communication transceiver for sending and/or receiving any wired or wireless communication. For example, the network interface hardware 110 may include an antenna, a modem, LAN port, Wi-Fi card, WiMax card, mobile communications hardware, near-field communication hardware, satellite communication hardware and/or any wired or wireless hardware for communicating with external computing devices.

Referring now to FIG. 2, the one or more memory modules 106 of the computing device 100 include a database 200, a car part selector module 202, a car part placement module 204, a physics module, 206, a background modification module 208, a ground truth generation module 210, an image capture module 212, a model training module 214, and an inference module 216. Each of the database 200, the car part selector module 202, the car part placement module 204, the physics module, 206, the background modification module 208, the ground truth generation module 210, the image capture module 212, the model training module 214, and the inference module 216 may be a program module in the form of operating systems, application program modules, and other program modules stored in one or more memory modules 106. Such a program module may include, but is not limited to, routines, subroutines, programs, objects, components, data structures and the like for performing specific tasks or executing specific data types as will be described below.

The database 200 may store information about virtual car parts. In particular, the database 200 may comprise a database of virtual car parts to be used to generate training data for a car parts detector, as disclosed herein. The database 200 may also store parameters associated with a machine learning model maintained by the computing device 100, as disclosed herein.

As discussed above, a car part picking robot may utilize a machine learning model to identify car parts in a container. As such, during operation, the robot may capture an image of a container (e.g., using a camera), and input the image into a machine learning model. The machine learning model may output locations of car parts in the image (e.g., bounding boxes around car parts in the image). The robot may then pick the identified car parts out of the container (e.g., using a robotic arm).

As such, a machine learning model may be trained to identify car parts in an image. However, as discussed above, using training data comprising images of real car parts may be expensive. It may be time consuming for humans to set up enough different arrangements of car parts to generate sufficient training data to train the model. Furthermore, it may be difficult and time consuming for humans to manually label each and every car part in each image. As such, in embodiments disclosed herein, synthetic data of car parts is used to generate training data for a car parts selector, rather than images of actual car parts.

Accordingly, the database 200 may store a plurality of potential virtual car parts. That is, the database 200 may store parameters associated with virtual car parts. This may include a variety of properties about each such virtual car parts, such as an image of the virtual car part, a size and shape of the virtual car part, a weight of the virtual car part, material properties of the virtual car part, and the like. In some examples, the database 200 may store computer-aided-drafting (CAD) files associated with virtual car parts. As such, as disclosed in further detail below, training data may be generated by selecting virtual car parts from the database 200, and generating images of the selected virtual car parts in a virtual container (e.g., a bin). As such, in some examples, the database 200 may store data about virtual containers that the virtual car parts may be placed in. Each such generated image may be used as one training example. A large number of training examples may be used as training data to train a machine learning model for a car parts detector, as discussed in further detail below.

Referring back to FIG. 2, the car part selector module 202 may select one or more virtual car parts from among the potential virtual car parts stored in the database 200 to generate a training example, as disclosed herein. In order to generate sufficient training data to train the machine learning model, a large number of training examples may be included with different training examples comprising a variety of different numbers and types of car parts in a variety of different configurations (e.g., in different positions and orientations). As such, the car part selector module 202 may select virtual car parts for each such training example.

In some examples, the car part selector module 202 may randomly select some number of virtual car parts from the database 200. In some examples, the car part selector module 202 may only select a number of virtual car parts up to a predetermined maximum number of virtual car parts (e.g., a maximum of 10 virtual car parts). Setting a maximum number of virtual car parts to select may prevent the car part selector module 202 from selecting too many car parts to fit in a virtual container.

In some examples, a user may specify the maximum number of virtual car parts that the car part selector module 202 may select. In these examples, the car part selector module 202 may first randomly select a number of virtual car parts to select (e.g., between 1 and the predetermined maximum number). The car part selector module 202 may then randomly select a number of virtual car parts equal to the selected random number. In some examples, a user may specify the number of car parts to be selected for a particular training example. In other examples, the car part selector module 202 may select different numbers of car parts for each training example. For example, the car part selector module 202 may randomly select 1 virtual car parts for a certain number of training examples, 2 virtual car parts for some number of other training examples, 3 virtual car parts for a number of other training examples, and so on, up to the maximum number of car parts to be selected. In some examples, a user may specify a range of sizes for the virtual car parts, and the car part selector module 202 may select only car parts within the specified range of sizes.

While the above examples describe the car part selector module 202 randomly selecting virtual car parts from the potential virtual car parts in the database 200, in other examples, the car part selector module 202 may select virtual car parts in a more deterministic, non-random manner. For example, the potential virtual car parts in the database 200 may be organized into categories, and for a particular training example, the car part selector module 202 may only select car parts within a single category. In other examples, the car part selector module 202 may select car parts from different categories. In some examples, the car part selector module 202 may select different combinations of car parts from the potential virtual car parts in the database 200 using some predetermined method (e.g., using Monte Carlo selection to determine the different combinations).

In some examples, the car part selector module 202 may also select a virtual container to place the selected virtual car parts in. In some examples, the car part selector module 202 may randomly select a virtual container from among potential virtual containers stored in the database 200. In other examples, a user may specify a virtual container to be used. In some examples, the car part selector module 202 may select different virtual containers for different training examples using a predetermined selection method.

Referring still to FIG. 2, the car part placement module 204 may place the virtual car parts selected by the car part selector module 202 in the virtual container selected by the car part selector module 202, as disclosed herein. As described herein, placing a virtual car part in a virtual container means determining a position and orientation of the virtual car part in the virtual container (e.g., by using a CAD program).

In embodiments, the car part placement module 204 may randomly select initial positions and initial orientations for the virtual car parts in the virtual container selected by the car part selector module 202. However, the car part placement module 204 may select the initial positions and initial orientations for each virtual car part in a training example such that the virtual car parts do not overlap with each other, which would not be physically possible for real car parts. In one example, the car part placement module 204 may randomly select an initial position and an initial orientation for a first virtual car part in a training example. The car part placement module 204 may then randomly select an initial position and an initial orientation for a second virtual car part in the training example such that the second virtual car part does not overlap with the first virtual car part. This process may be continued for each virtual car part in a training example. By randomly selecting different virtual car parts and placing them in a variety of different positions and orientations, training data may be generated containing a wide variety of training examples, which may allow the machine learning module to be better trained.

Referring still to FIG. 2, the physics module 206 may use a physics engine to simulate natural movement of the virtual car parts placed in the virtual container until they settle at resting positions and resting orientations. As discussed above, the car part placement module 204 may place the selected virtual car parts at random positions in the virtual container with random orientations. However, this may result in virtual car parts being placed in positions that would not be possible with real car parts. For example, virtual car parts may be placed at unnatural angles or on top of each other, which would cause real car parts to fall or tip over. As such, training the machine learning model with training examples having such

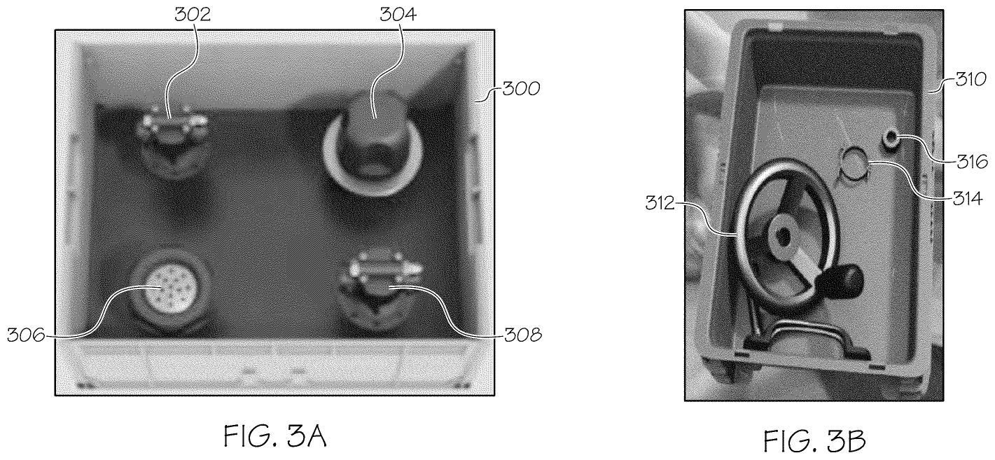

FIG. 3A shows an example image of virtual car parts 302, 304, 306, 308 that may be placed in virtual container 300 by the car part placement module 204. In the example of FIG. 3A, each virtual car part 302, 304, 306, 308 is placed at an unstable angle, such as balancing on a narrow end. If real car parts were arranged in this manner, they would tip over. As such, the image of FIG. 3A does not represent an actual possible arrangement of car parts, and as such would be a poor training example.

Accordingly, the physics module 206 may use a physics engine to simulate movement of the car parts placed by the car part placement module 204 in a virtual container, as disclosed herein. As discussed above, the database 200 stores physical properties of the potential virtual car parts (e.g., size, shape, weight, materials). As such, after the selected virtual car parts are placed in the virtual container, the physics module 206 may use a physics engine to determine how the virtual car parts would naturally move when placed in the initial positions with initial orientations.

For example, the physics engine may apply gravity to the virtual car parts and account for collisions between the virtual car parts and/or with the virtual container to allow the virtual car parts to settle at stable locations and orientations. Once the virtual car parts stop moving after being acted upon by the physics engine, their final positions and orientations, which may be referred to herein as resting positions and resting orientations, may be used for a training example. As such, the training examples used to train the machine learning model may comprise more realistic scenarios of how real car parts may be arranged in real life scenarios. FIG. 3B shows an image of virtual container 310 containing virtual car parts 312, 314, 316. In the example of FIG. 3B, the physics module 206 has been used to allow the virtual car parts 312, 314, 316 to settle at resting positions resting orientations. As such, the image of FIG. 3B shows car parts in an arrangement that could actually exist in real life.

Referring back to FIG. 2, the background modification module 208 may generate or modify a background of an image to be used in a training example. In particular, after the selected virtual car parts reach their resting positions and resting orientations, an image may be generated of the virtual car parts in the virtual container (e.g., a CAD program may output an image based on data in a CAD file). However, in a real life situation in which a robot is picking car parts from a container, there may be a background image around the container holding the car parts. If this is not accounted for in training the machine learning module, the robot may be confused and unable to distinguish between the car parts and items in the background. As such, the background modification module 208 may generate or modify a background of training example images in order to improve the robustness of the training data and the quality of the training of the machine learning model.

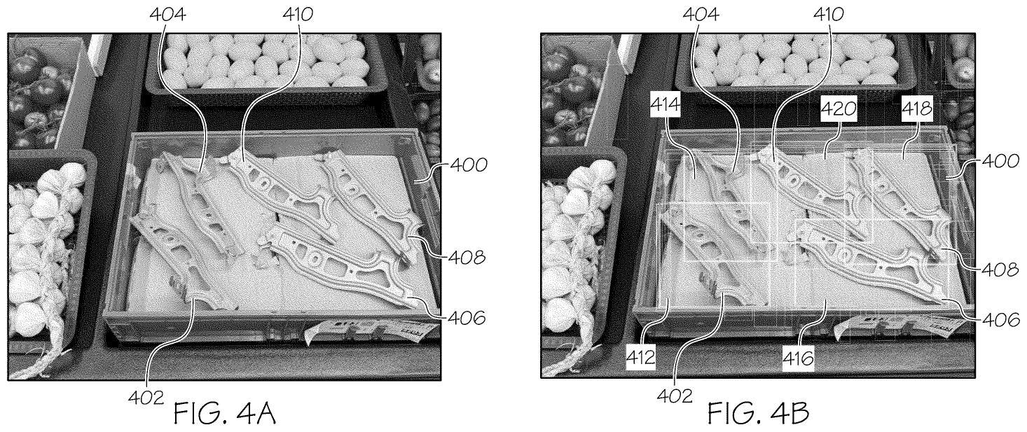

In some examples, the database 200 may contain a number of predetermined background images. As such, in embodiments the background modification module 208 may apply one of these predetermined background images to a training example image. For example, FIG. 4A shows a virtual container 400 containing virtual car parts 402, 404, 406, 408 and 410. The background of the image (the area outside of the virtual container 400) shows fruits and vegetables. This may be one predetermined background that may be selected by the background modification module 208. By including this type of background, the machine learning model may be trained not to confuse fruits and vegetables with car parts.

In some examples, the background modification module 208 may modify the background portion of training example images in a variety of different ways. For example, the background modification module 208 may modify colors of background items, shapes of background items, the number of background items, orientations of background items, and the like. As the computing device 100 generates training data comprising a plurality of training examples, the background modification module 208 may provide a variety of different backgrounds for the training examples. As such, the training data may be more varied and robust and may improve the performance of the machine learning module after training (e.g., by preventing the machine learning model from overfitting to a limited set of data).

Referring back to FIG. 2, the ground truth generation module 210 may generate ground truth data for each training example. As discussed above, a training example may comprise one or more virtual car parts arranged in a virtual container. As such, in order for the machine learning model to be trained using supervised learning techniques, ground truth data may be provided for each training example. In particular, ground truth data may comprise a bounding box around each virtual car part.

As discussed above, the properties of the potential virtual car parts are stored in the database 200. As further discussed above, the physics module 206 determines resting positions and resting orientations for the virtual car parts in the virtual container after applying a physics engine. Therefore, the ground truth generation module 210 may determine bounding boxes around the virtual car parts in the virtual container based on the resting positions and resting orientations of the virtual car parts and the physical properties of the virtual car parts (e.g., their size and shape). FIG. 4B shows an example image in which bounding boxes 412, 414, 416, 418, 420 are placed around the virtual car parts 402, 404, 406, 408, 410, respectively, in the virtual container 400. The ground truth data may be used to train the machine learning model, as discussed in further detail below.

Referring back to FIG. 2, the image capture module 212 may capture an image for a training example. In particular, the image capture module 212 may capture or generate an image of the selected virtual car parts in the selected virtual container at the determined resting positions and resting orientations along with the selected background image. For example, a CAD program may output an image of the virtual car parts in the virtual container using known techniques, and the image capture module 212 may apply the selected background to the image. FIG. 4A is an example image that may be generated by the image capture module 212.

Referring back to FIG. 2, the model training module 214 may train the machine learning model, as disclosed herein. As discussed above, the computing device 100 may maintain a machine learning model. In particular, the machine learning model may be trained to receive an input image, and output an identification of car parts in the image. In one example, the machine learning model may output a modified image with bounding boxes placed around the identified car parts. For example, the machine learning model may take the image of FIG. 4A as input, and output the image of FIG. 4B as output.

In embodiments, the model training module 214 may train the machine learning model using supervised learning techniques. In particular, the model training module 214 may receive training data comprising a plurality of training examples (e.g., images generated by the image capture module 212). The model training module 214 may also receive ground truth data associated with each training example (e.g., the image of each training example with bounding boxes around the car parts in the image). The model training module 214 may then train the machine learning model to identify car parts in an input image based on the training data and the ground truth data.

In the illustrated example, the machine learning model maintained by the computing device 100 is a neural network, which may have any type of neural network architecture. The model training module 214 may train the machine learning model using known supervised learning techniques. After the model is trained, an image containing one or more car parts may be input to the trained machine learning model, and the model may output the image with bounding boxes around the car parts in the image.

Referring back to FIG. 2, the inference module 216 may perform inference after the machine learning model has been trained. In particular, the inference module 216 may receive an image containing one or more car parts. The inference module 216 may input the image into the trained machine learning model, and the model may output a modified image showing bounding boxes around the car parts in the image.

In some examples, a robot may use the computing device 100 to pick car parts from a container. For example, the robot may capture an image of the container, and the inference module 216 may input the image into the trained machine learning model. The trained machine learning model may then output the image of the container with bounding boxes around any identified car parts in the image. The robot may then pick one or more of the identified car parts out of the container. In particular, a robot arm may grab items at locations in the container specified by the bounding boxes in the image output by the machine learning model, and remove the items it grabs. As such, the robot may use the machine learning model maintained by the computing device 100 to identify and pick items from a container.

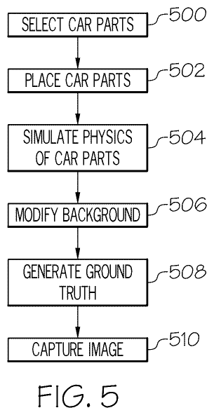

FIG. 5 depicts a flowchart of an example method that may be performed by the computing device 100. At step 500, the car part selector module 202 selects one or more virtual car parts to be placed in a virtual container. At step 502, the car part placement module 204 places the selected virtual car parts in the virtual container at initial positions with initial orientations. At step 504, the physics module 206 simulates movement of the virtual car parts in the virtual container using a physics engine until the virtual car parts arrive at resting positions with resting orientations.

At step 506, the background modification module 208 generates a background image for a training example. At step 508, the ground truth generation module 210 generates ground truth data comprising bounding boxes around the virtual car parts at the resting positions and resting orientations. At step 510, the image capture module 212 generates an image of the virtual car parts in the virtual container with the generated background image. The image generated by the image capture module 212 may be used as a training example as part of training data to train the machine learning model maintained by the computing device 100.

It should now be understood that embodiments described herein are directed to a method and system for training a car parts detector on synthetic data. By using synthetic data to train a car parts detector, a large amount of training data can be generated without the need for humans to collect and label the training data. Furthermore, by using realistic physics to determine positions and orientations of car parts in the training data, realistic training data images can be used to train a machine learning model to identify car parts from a captured image.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. A method comprising:
selecting one or more virtual car parts;
selecting initial positions and initial orientations for the selected one or more virtual car parts in a virtual container;
determining resting positions and resting orientations for the selected one or more virtual car parts in the virtual container based on the initial positions, the initial orientations, and a physics simulation;
generating an image of the selected one or more virtual car parts in the virtual container at the resting positions and the resting orientations; and
generating training data including the generated image as one training example.

2. The method of claim 1, further comprising training a machine learning model, using the training data, to generate a trained model to identify car parts in an input image.

3. The method of claim 1, further comprising:
receiving an input number of car parts to be included in the image; and
selecting a number of the one or more virtual car parts equal to the input number.

4. The method of claim 1, further comprising:
receiving an input range of sizes of car parts to be included in the image; and
selecting the one or more virtual car parts having sizes within the input range of sizes.

5. The method of claim 1, further comprising generating ground truth data comprising bounding boxes around the selected one or more virtual car parts in the image.

6. The method of claim 1, further comprising selecting the one or more virtual car parts from among a database of potential virtual car parts.

7. The method of claim 6, further comprising randomly selecting the one or more virtual car parts from among the database of potential virtual car parts.

8. The method of claim 1, further comprising randomly selecting the initial positions and the initial orientations of the virtual car parts.

9. The method of claim 1, further comprising generating a background for the image.

10. The method of claim 9, further comprising generating the background for the image by randomly selecting a background from among a plurality of potential background images.

11. The method of claim 2, further comprising:
receiving a second image that includes one or more car parts;
inputting the second image into the trained model; and
identifying the one or more car parts in the second image based on an output of the trained model.

12. A computing device comprising one or more processors configured to:
select one or more virtual car parts;
select initial positions and initial orientations for the selected one or more virtual car parts in a virtual container;
determine resting positions and resting orientations for the selected one or more virtual car parts in the virtual container based on the initial positions, the initial orientations, and a physics simulation;
generate an image of the selected one or more virtual car parts in the virtual container at the resting positions and the resting orientations; and
generate training data including the generated image as one training example.

13. The computing device of claim 12, wherein the one or more processors are further configured to train a machine learning model, using the training data, to generate a trained model to identify car parts in an input image.

14. The computing device of claim 12, wherein the one or more processors are further configured to generate ground truth data comprising bounding boxes around the selected one or more virtual car parts in the image.

15. The computing device of claim 12, wherein the one or more processors are further configured to select the one or more virtual car parts from among a database of potential virtual car parts.

16. The computing device of claim 12, wherein the one or more processors are further configured to generate a background for the image.

17. The computing device of claim 13, wherein the one or more processors are further configured to:
receive a second image that includes one or more car parts;
input the second image into the trained model; and
identify the one or more car parts in the second image based on an output of the trained model.

18. A non-transitory computer readable storage medium comprising a memory storing a program that, when executed by a processor, causes the processor to:
select one or more virtual car parts;
select initial positions and initial orientations for the selected one or more virtual car parts in a virtual container;
determine resting positions and resting orientations for the selected one or more virtual car parts in the virtual container based on the initial positions, the initial orientations, and a physics simulation;
generate an image of the selected one or more virtual car parts in the virtual container at the resting positions and the resting orientations; and
generate training data including the generated image as one training example.

19. The non-transitory computer readable storage medium of claim 18, wherein the program, when executed by the processor, further causes the processor to train a machine learning model, using the training data, to generate a trained model to identify car parts in an input image.

20. The non-transitory computer readable storage medium of claim 18, wherein the program, when executed by the processor, further causes the processor to generate ground truth data comprising bounding boxes around the selected one or more virtual car parts in the image.
